(19) United States
(12) Patent Application Publication
(10) Pub. No.: US 2025/0169141 A1
(43) Pub. Date: May 22, 2025

(54) High-Voltage Power Semiconductor Device and Method for Manufacturing the Same

(71) Applicant: NO.24 RESEARCH INSTITUTE OF CHINA ELECTRONICS TECHNOLOGY GROUP CORPORATION, Chongqing (CN)

(72) Inventors: Kaizhou TAN, Chongqing (CN); Tian XIAO, Chongqing (CN); Xiaoquan LI, Chongqing (CN); Xueliang XU, Chongqing (CN); Ying WANG, Chongqing (CN); Yongqing JIANG, Chongqing (CN); Yuxin WANG, Chongqing (CN); Guangbo LI, Chongqing (CN); Pengfei WANG, Chongqing (CN); Ying PEI, Chongqing (CN); Jian WU, Chongqing (CN); Ruzhang LI, Chongqing (CN); Zhikuan WANG, Chongqing (CN); Sheng QIU, Chongqing (CN); Peijian ZHANG, Chongqing (CN); Zhengyuan ZHANG, Chongqing (CN); Yukui LIU, Chongqing (CN)

(73) Assignee: NO.24 RESEARCH INSTITUTE OF CHINA ELECTRONICS TECHNOLOGY GROUP CORPORATION, Chongqing (CN)

(21) Appl. No.: 19/026,517

(22) Filed: Jan. 17, 2025

Related U.S. Application Data
(63) Continuation of application No. PCT/CN2023/089680, filed on Apr. 21, 2023.

(30) Foreign Application Priority Data
Aug. 25, 2022 (CN) 202211028299.2

(51) Int. Cl. H10D 64/00; H10D 62/10; H10D 84/01; H10D 84/83

(52) U.S. Cl. CPC H10D 64/115; H10D 62/109; H10D 64/112; H10D 64/117; H10D 84/0149; H10D 84/0151; H10D 84/839

(57) ABSTRACT

The present application provides a high-voltage power semiconductor device and a method for manufacturing the same. A plurality of second resistive field plate structures is arranged in a terminal region of an epitaxial layer and extends through the epitaxial layer in a first direction to a substrate. The second resistive field plate structures are arranged concentrically and discontinuously around an active region in a first plane. The second resistive field plate structures and a third resistive field plate structure thereon form a π-type combined resistive field plate structure.

### CROSS REFERENCE TO RELATED APPLICATION

The present disclosure is a continuation application of International Patent Application No. PCT/CN2023/089680, filed on Apr. 21, 2023, and claiming the priority to Chinese Application No. 202211028299.2 filed on Aug. 25, 2022, the contents of all of which are incorporated herein by reference in their entirety for all purposes.

### TECHNICAL FIELD

The present application belongs to the technical field of semiconductor devices and integrated circuits, and in particular, relates to a high-voltage power semiconductor device and a method for manufacturing the same.

### BACKGROUND

Inspired by the super-junction technology based on PN junction charge balance, some scholars have discovered that the internal resistive field plate has a similar effect to the PN junction super-junction and proposed some active device structures based on the internal resistive field plate, which has some advantages of relative PN junction super-junction performance.

### SUMMARY

In one aspect, a high-voltage power semiconductor device, including: a substrate including a front side and a back side arranged opposite to each other; an epitaxial layer arranged on the front side of the substrate, wherein the epitaxial layer includes an active region and a terminal region arranged adjacently to each other in a first plane, and the terminal region surrounds the active region; a cell functional unit arranged in the active region; a plurality of first resistive field plate structures arranged in the active region of the epitaxial layer and extending through the epitaxial layer along a first direction to the substrate, wherein the plurality of first resistive field plate structures extend in the first plane along a second direction; a plurality of second resistive field plate structures arranged in the terminal region of the epitaxial layer and extending through the epitaxial layer along the first direction to the substrate, wherein the plurality of second resistive field plate structures is concentrically arranged in the first plane, and the second resistive field plate structures discontinuously surrounds the active region in the first plane; a third resistive field plate structure arranged on the terminal region of the epitaxial layer and making ohmic contact with a top of each of the second resistive field plate structures; a first electrode arranged on the active region of the epitaxial layer and making in ohmic contact with a top of each of the first resistive field plate structures; a second electrode arranged on the epitaxial layer at a junction of the active region and the terminal region, wherein the second electrode is in ohmic contact with a side of the third resistive field plate structure close to the active region; a third electrode arranged on a side of the terminal region of the epitaxial layer away from the active region and making ohmic contact with the third resistive field plate structure; and a fourth electrode arranged on the back side of the substrate and making ohmic contact with a bottom of each of the first resistive field plate structures and a bottom of each of the second resistive field plate structures through the substrate, wherein the first plane is parallel to the front side of the substrate, and the first direction is perpendicular to the first plane.

In one or more embodiments of the present application, in the first plane, the first resistive field plate structures are equally spaced at a first interval along a third direction, and the second resistive field plate structures are equally spaced at a second interval along any direction orthogonal to the first direction, the second interval is smaller than the first interval, and the third direction is perpendicular to the second direction.

In one or more embodiments of the present application, in the first plane, the second resistive field plate structure includes a plurality of resistive field plate segments, and in each of the second resistive field plate structures, the resistive field plate segments are arranged at intervals around the active region.

In one or more embodiments of the present application, in the first plane, in each of the second resistive field plate structures, two adjacent resistive field plate segments are equally spaced at a third interval, the length of the resistive field plate segment is less than or equal to five times the second interval, and the length of the resistive field plate segment is greater than or equal to the third interval.

In one or more embodiments of the present application, the high-voltage power semiconductor device also includes a PN junction terminal voltage-withstanding region, the PN junction terminal voltage-withstanding region is arranged in the terminal region of the epitaxial layer and is located on a top of the epitaxial layer; in the first plane, the PN junction terminal voltage-withstanding region surrounds the active region, an inner edge of the PN junction terminal voltage-withstanding region is connected to the second electrode through a metal contact hole, an outer edge of the PN junction terminal voltage-withstanding region is surrounded by the third electrode, and each of the second resistive field plate structures passes through the PN junction terminal voltage-withstanding region.

In one or more embodiments of the present application, the PN junction terminal voltage-withstanding region includes at least one of a field limiting ring PN junction terminal voltage-withstanding region, a RESURF type PN junction terminal voltage-withstanding region, and a variable doping type PN junction terminal voltage-withstanding region.

In one or more embodiments of the present application, the cell functional units at least include: a diode cell functional unit, a MOSFET cell functional unit, a triode cell functional unit, a JFET cell functional unit, and an IGBT cell functional unit.

In another aspect, a method for manufacturing a high-voltage power semiconductor device, including: providing a substrate including a front side and a back side arranged opposite to each other, and forming an epitaxial layer on the front side of the substrate, wherein the epitaxial layer includes an active region and a terminal region arranged adjacent to each other in a first plane, and the terminal region surrounds the active region; forming a cell functional unit in the active region of the epitaxial layer; forming a plurality of first trenches in the active region of the epitaxial layer, and forming a plurality of second trenches in the terminal region of the epitaxial layer, wherein the first trenches pass through the cell functional unit and the epitaxial layer along a first direction and enter the substrate, and the second trenches pass through the epitaxial layer along the first direction and enter the substrate; forming first resistive field plate structures in the first trenches, forming second resistive field plate structures in the second trenches, and forming a third resistive field plate structure on a surface of the terminal region of the epitaxial layer, wherein the third resistive field plate structure is in ohmic contact with a top of each of the second resistive field plate structures; and forming a first electrode, a second electrode, and a third electrode that are mutually independent on the epitaxial layer, and forming a fourth electrode on the back side of the substrate, wherein the first electrode is in ohmic contact with a top of each of the first resistive field plate structures, the second electrode is in ohmic contact with a side of the third resistive field plate structure close to the active region, the third electrode is in ohmic contact with a side of the third resistive field plate structure away from the active region, and the fourth electrode is in ohmic contact with a bottom of each of the first resistive field plate structures and a bottom of each of the second resistive field plate structures through the substrate, wherein the first plane is parallel to the front side of the substrate, the first direction is perpendicular to the first plane, and the first trench and the second trench are formed in a same process.

In one or more embodiments of the present application, after providing the substrate and forming the epitaxial layer and before forming the first trench and the second trench, the method for manufacturing a power semiconductor device further includes: forming a PN junction terminal voltage-withstanding region in the terminal region of the epitaxial layer, wherein in the first plane, the PN junction terminal voltage-withstanding region surrounds the active region.

In one or more embodiments of the present application, in the first plane, each of the first trenches extends in the first plane along a second direction, and each of the first trenches is equally spaced at a first interval along a third direction, the second trenches are arranged concentrically and discontinuously around the active region in the first plane, and the second trenches are equally spaced at a second interval in any direction orthogonal to the first direction, and the second interval is smaller than the first interval, and the third direction is perpendicular to the second direction.

In one or more embodiments of the present application, in the first plane, the second trench includes a plurality of trench segments, and in each of the second trenches, the trench segments are arranged at intervals around the active region.

In one or more embodiments of the present application, in the first plane, in each of the second trenches, two adjacent trench segments are equally spaced at a third interval, the length of the trench segment is less than or equal to five times the second interval, and the length of the trench segment is greater than or equal to the third interval.

In one or more embodiments of the present application, forming the first resistive field plate structures in the first trench, forming the second resistive field plate structures in the second trench, and forming the third resistive field plate structure on the surface of the terminal region of the epitaxial layer include: forming trench field plate dielectric layers in the first trench and the second trench respectively; removing the trench field plate dielectric layers at a bottom of the first trench and at a bottom of the second trench; and depositing semi-insulating polysilicon material and etching, wherein the semi-insulating polysilicon material in the first trench and the trench field plate dielectric layer at a sidewall position constitute the first resistive field plate structure, the semi-insulating polysilicon material in the second trench and the trench field plate dielectric layer at the sidewall position constitute the second resistive field plate structure, and the semi-insulating polysilicon material remaining on the terminal region of the epitaxial layer and in ohmic contact with the top of each second resistive field plate structure constitutes the third resistive field plate structure.

In one or more embodiments of the present application, forming the first electrode, the second electrode, and the third electrode that are mutually independent on the epitaxial layer and forming the fourth electrode on the back side of the substrate include: forming an isolation dielectric layer on the epitaxial layer; etching the isolation dielectric layer to form a plurality of first contact holes on the active region of the epitaxial layer, and forming a second contact hole and a third contact hole that are mutually independent on the terminal region of the epitaxial layer, wherein the third contact hole surrounds the second contact hole, and the plurality of first contact holes correspondingly exposes tops of the first resistive field plate structures, and the second contact hole and the third contact hole expose tops of two ends of the third resistive field plate structure respectively; forming a first metal layer on the isolation dielectric layer; etching the first metal layer to form the first electrode, the second electrode, and the third electrode, wherein the first electrode passes through the first contact hole to make ohmic contact with the top of each of the first resistive field plate structures, the second electrode passes through the second contact hole to make ohmic contact with a top of an end of the third resistive field plate structure close to the active region, and the third electrode passes through the third contact hole to make ohmic contact with a top of an end of the third resistive field plate structure away from the active region; and forming a second metal layer on the back side of the substrate to obtain the fourth electrode, wherein the fourth electrode is in ohmic contact with the bottom of each of the first resistive field plate structures and the bottom of each of the second resistive field plate structures through the substrate.

### BRIEF DESCRIPTION OF DRAWINGS

FIG. 1 is a schematic diagram showing the structure of a high-voltage power semiconductor device according to one or more embodiments of the present application.

FIG. 2 is a schematic diagram showing the operations of a method for manufacturing a high-voltage power semiconductor device according to one or more embodiments of the present application.

FIGS. 3 to 10 are cross-sectional views showing the process flow of the method for manufacturing a high-voltage power semiconductor device according to one or more embodiments of the present application along a section line AA′ in FIG. 1.

FIG. 11 is a cross-sectional view of the structure of a high-voltage power semiconductor device along a line BB′ in FIG. 1 according to one or more embodiments of the present application.

FIG. 12 is a schematic diagram showing S2 according to one or more embodiments of the present application.

FIG. 13 is a schematic diagram showing the operations for forming a first resistive field plate structure, a second resistive field plate structure, and a third resistive field plate structure according to one or more embodiments of the present application.

FIG. 14 is a schematic diagram showing the operations for forming a first electrode, a second electrode, a third electrode, and a fourth electrode according to one or more embodiments of the present application.

### DESCRIPTION OF FIGURE NUMBERS

1—substrate, 2—epitaxial layer, 3—first resistive field plate structure, 4—second resistive field plate structure, 5—third resistive field plate structure, 6—first electrode, 7—second electrode, 8—third electrode, 9—fourth electrode, 10—PN junction terminal voltage-withstanding region, 11—isolation dielectric layer, 12—first metal layer, 13—second metal layer, 00—cell functional unit, 01—equipotential ring, 02—trench field plate dielectric layer, 03—semi-insulating polysilicon material, 20—top dielectric layer, a—active region of epitaxial layer 2, b—terminal region of epitaxial layer 2, T1—first trench, T2—second trench, D1—dimension (trench width) of first trench T1 along third direction, L1—dimension of first trench T1 along first direction, L2—dimension of region occupied by discontinuous deep-trench type internal resistive field plate in terminal region in lateral direction, W1—distance (first interval) between two adjacent first resistive field plate structures 3 in first plane, W2—minimum distance (second interval) between two adjacent second resistive field plate structures 4 (or second trench T2) in first plane, W3—third interval, K1—first contact hole, K2—second contact hole, K3—third contact hole, K4—fourth contact hole, K5—fifth contact hole, AA′, BB′, CC′—section lines.

### DESCRIPTION OF EMBODIMENTS

The following describes the embodiments of the present application through specific examples, and those skilled in the art can easily understand other advantages and effects of the present application from the contents disclosed in this specification. The present application can also be implemented or applied through other specific embodiments, and the details in this specification can also be modified or changed in various ways based on different viewpoints and applications without departing from the spirit of the present application.

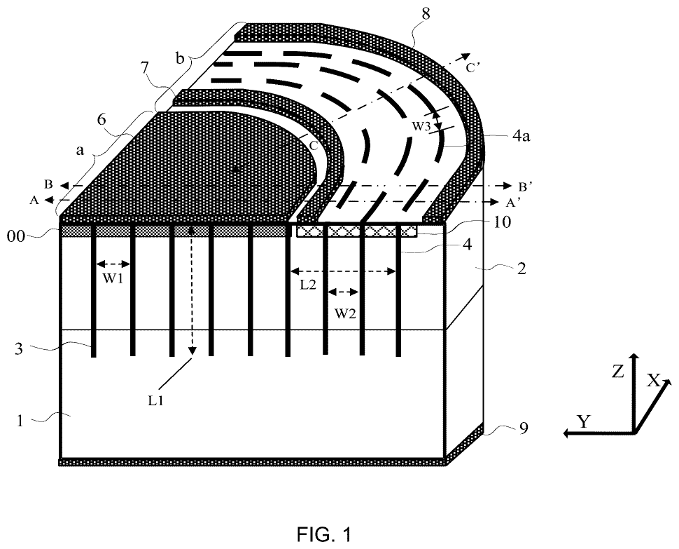

Please refer to FIGS. 1 to 11. It should be noted that the illustrations provided in this embodiment only illustrate the basic concept of the present application in a schematic manner. The illustrations only show the components related to the present application rather than being drawn according to the number, shape, and size of the components in actual implementation. The type, quantity, and scale of each component in actual implementation can be changed arbitrarily and reasonably, and the component layout may also be more complex. The structure, proportion, size, etc. illustrated in the illustrations attached to this specification are only used to match the content disclosed in the specification for people familiar with this technology to understand and read, and are not used to limit the restrictive conditions that the present application can be implemented, so they have no technical substantive significance in terms of limitation. Any structural modification, change in proportional relationship, or adjustment of size should still fall within the scope of the technical content disclosed by the present application without affecting the effect and purpose that can be achieved by the present application.

Since the 1970s, resistive field plates have been used in high-voltage power semiconductor devices, but they are mainly used on the surface or edge of high-voltage power semiconductor devices, and rarely used inside the semiconductor devices.

In addition, since the active cell structure of the high-voltage power semiconductor device bears a high voltage, to improve its voltage resistance, it is necessary to set a voltage-withstanding terminal structure on the periphery of the active cell structure. However, like the PN junction super-junction structure, in the device structure, the active cell structure precedes the voltage-withstanding terminal structure, and the conventional technique has not yet found a voltage-withstanding terminal structure based on an internal resistive field plate. Furthermore, due to the lack of material models and structural specificity of existing numerical calculation simulation tools, it is also difficult to accurately design a voltage-withstanding terminal structure based on an internal resistive field plate using numerical simulation tools.

Therefore, how to design a voltage-withstanding terminal structure for high-voltage power semiconductor devices based on an internal resistive field plate is a technical problem that needs to be solved urgently.

The inventors have found that in current devices having a super-junction structure or quasi-super-junction structure, the breakdown of the cell structure is relatively easy, while the design of the peripheral terminal structure is relatively more difficult, and its effect on improving the voltage-withstanding performance of the device is limited.

Based on this, the present application proposes a technical solution for a terminal voltage-withstanding structure based on an internal resistive field plate in a high-voltage power semiconductor device, in which: a plurality of internal resistive field plate structures is formed in a terminal region surrounding an active region, and the second resistive field plate structures are concentrically and discontinuously arranged around the active region in a first plane. When voltage is applied, the tightly coupled second resistive field plate structures form a uniform three-dimensional electric field distribution that is open and divergent in all directions, which may optimize the guiding and binding effect of the terminal region on the charges in a space depletion region in the active region, so as to improve the voltage-withstanding performance of the entire power semiconductor device. Moreover, the formed three-dimensional electric field has gaps, which may appropriately disperse the space charges and prevent the power lines from being too concentrated, so as to improve the structural stability of the terminal region and the entire high-voltage power semiconductor device.

As shown in FIG. 1, one or more exemplary embodiments of the present application provide a high-voltage power semiconductor device, which includes: a substrate 1 having a front side and a back side that are arranged opposite to each other; an epitaxial layer 2 arranged on the front side of the substrate 1 and including an active region a and a terminal region b which are arranged adjacent to each other in a first plane, wherein the terminal region b surrounds the active region a; a cell functional unit 00 arranged in the active region a; a plurality of first resistive field plate structures 3 arranged in the active region a of the epitaxial layer 2 and extending through the epitaxial layer 2 to the substrate 1 along a first direction (Z-axis direction in FIG. 1), wherein the plurality of first resistive field plate structures 3 extend in the first plane (i.e., XY plane in FIG. 1) along a second direction (Y-axis direction in FIG. 1); a plurality of second resistive field plate structures 4 arranged in the terminal region b of the epitaxial layer 2 and extending through the epitaxial layer 2 along the first direction to the substrate 1, wherein the plurality of second resistive field plate structures 4 are concentrically located in the first plane, and the second resistive field plate structures 4 are discontinuously arranged around the active region a in the first plane; a third resistive field plate structure (not shown in FIG. 1) arranged on the terminal region b of the epitaxial layer 2 and is in ohmic contact with the top of each second resistive field plate structure 4; a first electrode 6 arranged on the active region a of the epitaxial layer 2 and is in ohmic contact with the top of each first resistive field plate structure 3; a second electrode 7 arranged at a junction of the active region a and the terminal region b on the epitaxial layer 2 and is in ohmic contact with a side of the third resistive field plate structure 5 close to the active region; a third electrode 8 arranged on the side of the terminal region b of the epitaxial layer 2 away from the active region a and is in ohmic contact with the third resistive field plate structure 5; and a fourth electrode 9 arranged on the back side of the substrate 1 and is in ohmic contact with the bottom of each first resistive field plate structure 3 and the bottom of each second resistive field plate structure 4 through the substrate 1, wherein the first plane is parallel to the front side of the substrate 1, and the first direction is perpendicular to the first plane.

In one or more embodiments, as shown in FIG. 1, the epitaxial layer 2 includes the active region a and the terminal region b arranged adjacent to each other in the first plane, and the terminal region b surrounds the active region a. It should be noted that FIG. 1 only shows ¼ of the complete power semiconductor device, and the structure of the remaining part is the same as that of the shown ¼ of the device.

In one or more embodiments, a cell functional unit 00 is formed in the active region (also called cell region) a of the epitaxial layer 2, and the cell functional unit 00 at least includes a diode cell functional unit, a MOSFET cell functional unit, a triode cell functional unit, a JFET cell functional unit, and an IGBT cell functional unit, which are not limited here.

In one or more embodiments, the impurity conductivity type of the epitaxial layer 2 and the impurity conductivity type of the substrate 1 are the same. In one or more embodiments, the impurity conductivity type of the epitaxial layer 2 and the impurity conductivity type of the substrate 1 are of different impurity conductivity types in the case of small implantation of both.

In one or more embodiments, as shown in FIG. 1, the high-voltage power semiconductor device also includes a PN junction terminal voltage-withstanding region 10. The PN junction terminal voltage-withstanding region 10 is arranged in the terminal region b of the epitaxial layer 2 and is located on the top of the epitaxial layer 2. In the first plane, the PN junction terminal voltage-withstanding region 10 surrounds the active region a, and the inner edge of the PN junction terminal voltage-withstanding region 10 is connected to the second electrode 7 through a metal contact hole. The outer edge of the PN junction terminal voltage-withstanding region 10 is surrounded by the third electrode 8, and each second resistive field plate structure 4 passes through the PN junction terminal voltage-withstanding region 10.

In one or more embodiments, the PN junction terminal voltage-withstanding region 10 includes at least one of a voltage-withstanding field limiting ring PN junction terminal region, a RESURF type PN junction terminal voltage-withstanding region, and a variable doping type PN junction terminal voltage-withstanding region. In one or more embodiments, the PN junction terminal voltage-withstanding region 10 has other conventional effective planar PN junction structures.

In one or more embodiments, as shown in FIG. 1, in the first plane, the first resistive field plate structures 3 are equally spaced at a first interval W1 along a third direction (X-axis direction in FIG. 1), and the second resistive field plate structures 4 are equally spaced at a second interval W2 along any direction orthogonal to the first direction, and the second interval W2 is smaller than the first interval W1, wherein the third direction is perpendicular to the second direction.

It should be noted that the number of the discontinuous second resistive field plate structures 4 in the terminal region b needs to satisfy that the lateral space L2 occupied by the second resistive field plate structures 4 is greater than or equal to the dimension L1 of the first resistive field plate structure 3 in the first direction.

In one or more embodiments, as shown in FIG. 1, in the first plane, the second resistive field plate structure 4 includes a plurality of resistive field plate segments 4a, and in each second resistive field plate structure 4, the resistive field plate segments 4a are arranged one by one at intervals along the direction surrounding the active region a and are connected end to end. In the first plane, in each second resistive field plate structure 4, two adjacent resistive field plate segments 4a are equally spaced at a third interval W3, the length of the resistive field plate segment 4a is less than or equal to five times the second interval W2, and the length of the resistive field plate segment 4a is greater than or equal to the third interval W3.

In one or more embodiments, as shown in FIG. 1, in the first plane, when viewed along any direction orthogonal to the first direction, the gaps (gaps corresponding to W3) between any two adjacent second resistive field plate structures 4 are mutually staggered, that is, when viewed along a direction orthogonal to the first direction such as section line AA′, section line BB′, or section line CC′, any two adjacent second resistive field plate structures 4 are not both gaps simultaneously.

In one or more embodiments, in the first plane, the shape of the second electrode 7 at the corner is not limited to the arc shape shown in FIG. 1, but may also be a quarter ellipse, a cut corner, or a straight line, etc., instead of a right angle, so as to optimize the electric field distribution at the corner and reduce the tip discharge effect. Correspondingly, the shape of the third electrode 8 at the corner is not limited to the arc shape shown in FIG. 1, but may also be an ellipse, a broken line, or a cut corner, etc., which is not limited here.

In one or more embodiments of the present application, the first electrode 6 and the second electrode 7 may differ by a control voltage of a device, such as the gate-source voltage of VDMOS; in one or more embodiments of the present application, the first electrode 6 and the second electrode 7 are of the same potential and essentially become one electrode, that is, for the convenience of the actual wiring of the device, the second electrode 7 can be merged with the first electrode 6.

In one or more embodiments of the present application, like the traditional one-dimensional planar process, the high-voltage power semiconductor device may also include an equipotential ring at the outermost edge of the terminal (not shown in FIG. 1). The equipotential ring is arranged in the outer top area of the terminal region b, corresponding to the third electrode 8. The distance between the metal contact hole adjacent to the equipotential ring and the PN junction terminal voltage-withstanding region 10 is greater than or equal to zero, and the equipotential ring is located on the right side of the metal contact hole.

In one or more embodiments, in the terminal region b, a plurality of internal deep-trench second resistive field plate structures 4 and the horizontally transverse third resistive field plate structure thereon constitute a rr-type combined resistive field plate structure, and when the device is turned off, the two ends of the horizontally transversely arranged third resistive field plate structure are respectively and equivalently electrically connected to the second electrode 7 and the third electrode 8 of the device with the highest voltage difference therebetween.

It should be noted that, even if the voltage difference between the electrodes of the combined resistive field plate composed of either the first resistive field plate structure 3 in the active region a or the discontinuous second resistive field plate structure 4 in the terminal region b and the horizontal third resistive field plate structure on the terminal region b is not the highest voltage difference, but is slightly smaller than the highest voltage difference, it does not seriously affect or reduce the maximum operating voltage of the high-voltage semiconductor device composed of the active region a and the terminal region b.

It should also be noted that when the horizontally lateral third resistive field plate structure exists, even if the PN junction terminal voltage-withstanding region 10 with opposite doping types to the surface of the epitaxial layer 2 does not exist in the terminal region b, the high-voltage semiconductor device composed of the active region a and the terminal region b still has a relatively high operating voltage, although generally not as high as the operating voltage when the PN junction terminal voltage-withstanding region 10 exists.

It should also be noted that the equipotential ring being located on the left side of the metal contact hole, or even being in contact with or intersecting with the PN junction terminal voltage-withstanding region 10, does not necessarily cause a serious drop in the device breakdown voltage.

In one or more embodiments, the third resistive field plate structure can be a composite structure of a resistive field plate and a metal field plate, which includes both the resistive field plate and the metal field plate. If the metal field plate and the resistive field plate exist at the same time, the metal field plate is located below the resistive field plate, closer to the surface of the epitaxial layer 2, and the presence of the metal field plate cannot destroy the combined resistive field plate structure of the third resistive field plate structure and the second resistive field plate structure 4.

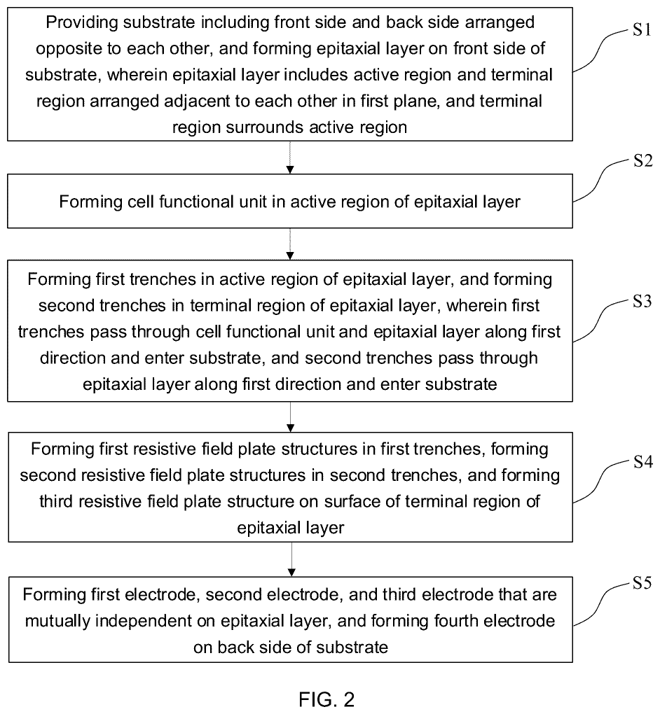

As shown in FIG. 2, one or more embodiments of the present application further provide a method for manufacturing a high-voltage power semiconductor device, the method includes: S1) providing a substrate 1 including a front side and a back side arranged opposite to each other, and forming an epitaxial layer 2 on the front side of the substrate 1, wherein the epitaxial layer 2 includes an active region a and a terminal region b arranged adjacent to each other in a first plane, the terminal region b surrounding the active region a; S2) forming a cell functional unit in the active region a of the epitaxial layer 2; S3) forming a plurality of first trenches T1 in the active region a of the epitaxial layer 2, and forming a plurality of second trenches T2 in the terminal region b of the epitaxial layer 2, wherein the first trenches T1 pass through the cell functional unit 00 and the epitaxial layer 2 along a first direction and enter the substrate 1, and the second trenches T2 pass through the epitaxial layer 2 along the first direction and enter the substrate 1; S4) forming a first resistive field plate structure 3 in the first trench T1, forming a second resistive field plate structure 4 in the second trench T2, and forming a third resistive field plate structure 5 on the surface of the terminal region b of the epitaxial layer 2, wherein the third resistive field plate structure 5 is in ohmic contact with the top of each second resistive field plate structure 4; S5) forming a first electrode 6, a second electrode 7, and a third electrode 8 that are mutually independent on the epitaxial layer 2, and forming a fourth electrode 9 on the back side of the substrate 1, wherein the first electrode 6 is in ohmic contact with the top of each first resistive field plate structure 3, the second electrode 7 is in ohmic contact with the side of the third resistive field plate structure 5 close to the active region a, the third electrode 8 is in ohmic contact with the side of the third resistive field plate structure 5 away from the active region a, and the fourth electrode 9 is in ohmic contact with the bottom of each first resistive field plate structure 3 and the bottom of each second resistive field plate structure 4 through the substrate 1, wherein the first plane is parallel to the front surface of the substrate 1, the first direction is perpendicular to the first plane, and the first trench T1 and the second trench T2 are formed in the same process.

The implementation of the scheme is illustrated below using a high-voltage diode (i.e., the cell functional unit in the active region a is a diode cell functional unit) as an example, and other methods that can realize the content and features of the present application should not be considered to be different from this scheme. The specific process method for forming the deep-trench type internal resistive field plate has been described in detail in our previously published patent application documents, and other processes are familiar to those skilled in the art. The present application will not specifically describe the details of the specific deep-trench type internal resistive field plate process here, but will only reasonably describe the main process methods, so as to illustrate the necessary process steps and methods for realizing the aforementioned terminal structure in the implementation examples. The processes described in the following examples are all existing mature processes, and are not described in a very detailed way. General technicians in this industry understand and comprehend them.

Before executing the manufacturing process, the key dimensions and shape structures of the high-voltage power semiconductor device are first designed. By computer-aided design, taking the voltage-withstanding terminal structure and device using a 450V active region as a diode as an example, it is determined that the first interval W1 between two adjacent first resistive field plate structures 3 in the active region a along the third direction is selected as 5 μm, the size (or depth) L1 of the first resistive field plate structure 3 along the first direction is selected as 27 μm, and the width of the first resistive field plate structure 3 is 1 μm. According to the computer-aided design results, an N+ highly doped semiconductor substrate material 1 (i.e., substrate 1) and an N− epitaxial wafer of the same conductivity type thereon (i.e., epitaxial layer 2) are prepared, the resistivity of the epitaxial layer 2 is selected as 2 to 4 Ω·cm, the doping concentration is selected as 1.1 to 2.2×10¹⁵ cm⁻², and the thickness of the epitaxial layer 2 is 25 μm, which is slightly smaller than the depth L1 of the deep-trench type internal resistive field plate mentioned above, to meet the requirement that the bottom of the deep-trench type internal resistive field plate enters the substrate 1. The structure of the active region a can be determined by referring to the computer-aided design verification and finally corrected through actual process experiments.

After the approximation of the deep-trench internal resistive field plate structure in the active region by the computer-aided design, the parameters of the deep-trench internal resistive field plate structure in the active region are used as a reference to determine that the interval W2 of the discontinuous deep-trench internal resistive field plates in the terminal region is 4.5 μm, the size L2 of the area laterally occupied by the discontinuous deep-trench internal resistive field plates in the terminal region is 50 μm, which is approximately twice the depth L1 of the deep-trench internal resistive field plate, the distance from the PN junction terminal voltage-withstanding area 10 to the right beyond the rightmost discontinuous deep-trench internal resistive field plate in the terminal region is 2 μm, and the size from the PN junction terminal voltage-withstanding area 10 to the metal contact hole adjacent to the equipotential ring is 12 μm. In addition, the gap size W3 of the discontinuous deep-trench type internal resistive field plates in the terminal region is taken as 1.5 μm to 2 μm, and the length of the continuous part of the discontinuous deep-trench type internal resistive field plate in the terminal region (that is, the length of the resistive field plate segment 4a in the first plane) is 6.4 μm, which is 1.6 times of W2, less than 5 times of W2, and greater than the gap size W3 (1.5 μm) of the internal resistive field plate (see FIG. 1).

After the geometrical dimensions of the high-voltage power semiconductor device are determined, subsequent process preparation is performed.

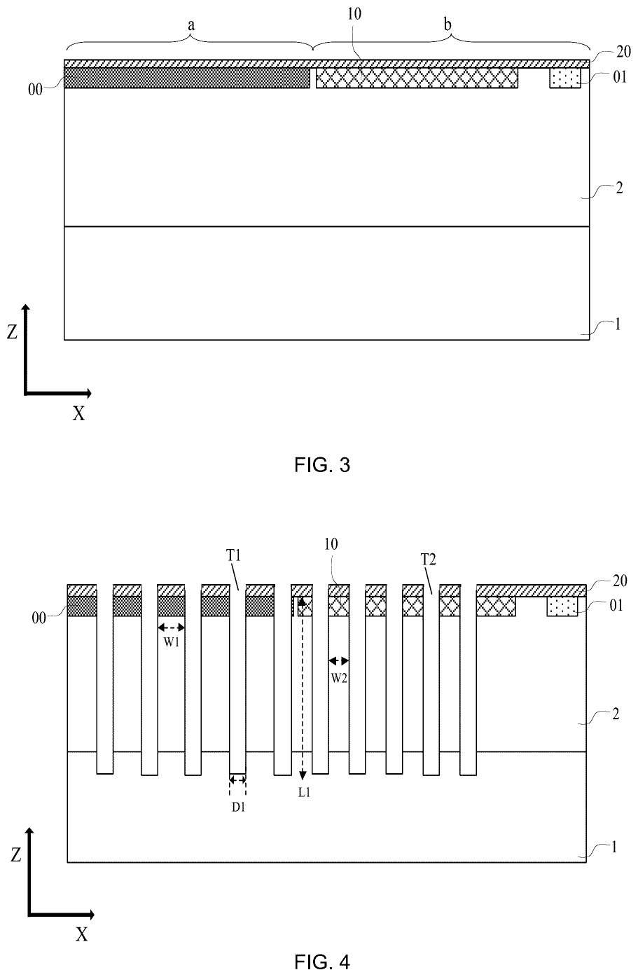

In one or more embodiments, as shown in FIG. 3, in S1, a substrate 1 is provided as the drain region of the device, which is an N-type doped semiconductor material (such as silicon, silicon carbide, gallium arsenide, etc.); an epitaxial layer 2 is formed on the substrate 1 as the drift region of the device, and the epitaxial layer 2 is also an N-type doped semiconductor material. In addition, the substrate 1 is heavily doped, and the epitaxial layer 2 is lightly doped; the thickness of the epitaxial layer 2 can be flexibly designed according to the situation.

In one or more embodiments, as shown in FIG. 3, the epitaxial layer 2 includes an active region a and a terminal region b arranged adjacent to each other in a first plane, and the terminal region b surrounds the active region a. It should be noted that FIG. 3 only shows ¼ of the entire power semiconductor device, and the structure of the remaining part is the same as that of the shown ¼ of the device.

In detail, between S1 and S2, the method for manufacturing the power semiconductor device further includes: forming a photolithography alignment mark on the epitaxial layer 2 using an industry-standard method to facilitate alignment of subsequent process steps.

In one or more embodiments, as shown in FIG. 3, between S1 and S2, the method for manufacturing a power semiconductor device further includes: oxidizing the top of the epitaxial layer 2 using a general process to obtain a top dielectric layer 20. For example, wet oxidation at 950° C. is performed for 20 minutes to obtain a top dielectric layer 20 having a thickness of about 60 nm±10 nm.

In one or more embodiments, as shown in FIG. 3, in S2, a cell function unit 00 is formed in the active region a of the epitaxial layer 2. Since a simple diode is used as an example to illustrate the technical solution of the present application, the functional active region a of the device can be simply photolithographically processed, with boron implanted with photoresist under the implantation conditions of 100 Kev and 5×10¹⁴ cm⁻².

In one or more embodiments, as shown in FIG. 3 and FIG. 12, in S2, a PN junction terminal voltage-withstanding region 10 is simultaneously formed in the terminal region b of the epitaxial layer 2. In the embodiment of the present application, the PN junction terminal voltage-withstanding region 10 is doped with RESURF, and the RESURF doped region is photolithographically processed, and a photoresist is used as a shielding mask to perform boron ion implantation at (2˜5)×10¹² cm⁻² and 170 kev, to form a RESURF doped region, that is, a PN junction terminal voltage-withstanding region 10.

In one or more embodiments, in S2, ion diffusion is then performed under the protection of an inert gas to perform impurity diffusion and activation, such as ion diffusion at 1050° C. for 90 minutes, to form a cell functional unit 00 in the active region a of the epitaxial layer 2 and a PN junction terminal voltage-withstanding area 10 in the terminal region b of the epitaxial layer 2.

The cell functional unit 00 formed in the active region a may be a diode cell functional unit, a MOSFET cell functional unit, a minority carrier small injection transistor cell functional unit, an IGBT cell functional unit, etc. (in the case of IGBT, the substrate is at least partially P-type doped), which is not limited here.

In detail, as shown in FIG. 3, between S2 and S3, the method for manufacturing a power semiconductor device further includes: performing equipotential ring lithography at the outer edge of the terminal region b of the epitaxial layer 2, using photoresist as a shielding mask, and performing phosphorus ion implantation at 5×10¹⁵ cm⁻² and 170 kev, to form an equipotential ring 01, wherein the equipotential ring 01 is spaced apart from the PN junction terminal voltage-withstanding region 10.

In one or more embodiments, as shown in FIG. 4, between S2 and S3, the method for manufacturing the power semiconductor device further includes: depositing a layer of silicon dioxide of 800 nm to 900 nm by low pressure chemical vapor (LPCV) deposition to increase the thickness of the top dielectric layer 20, which is used as a masking layer for subsequent etching for the deep trench and the oxide layer at the bottom of the deep trench.

In detail, as shown in FIG. 4, in S3, a plurality of first trenches T1 are formed in the active region a of the epitaxial layer 2, a plurality of second trenches T2 are formed in the terminal region b of the epitaxial layer 2. For example, a plurality of first trenches T1 are formed in the cell region of the epitaxial layer 2, and a plurality of second trenches T2 are formed in the terminal region b of the epitaxial layer 2. The first trenches T1 pass through the cell functional unit 00 and the epitaxial layer 2 along the first direction into the substrate 1, and the second trenches T2 pass through the epitaxial layer 2 along the first direction into the substrate 1.

In more detail, as shown in FIG. 4, a photolithography machine and a corresponding photolithography plate are used to expose the positions of the first resistive field plate structure 3 and the second resistive field plate structure 4, and then a dry etching process is used to sequentially etch the top dielectric layer 20, the epitaxial layer 2, and the substrate 1 and simultaneously form a first trench T1 and a second trench T2, wherein the depth L1 of the first trench T1 (or the second trench T2) vertically entering the epitaxial layer 2 and the substrate 1 is 27 μm, and the width D1 of the trench is 0.8 to 1.2 μm.

In one or more embodiments, as shown in FIG. 4, in the first plane, the plurality of first trenches T1 extends in the first plane along the second direction, and the plurality of first trenches T1 are equally spaced at the first interval W1 along the third direction, and the second trenches T2 are concentrically and discontinuously arranged around the active region a in the first plane, and the second trench T2 are equally spaced at the second interval W2 in any orthogonal direction to the first direction, and the second interval W2 is smaller than the first interval W1, wherein the third direction is perpendicular to the second direction.

In more detail, as shown in FIG. 4, the first interval W1 between two adjacent first trenches T1 in the active region a along the third direction is selected to be 5 μm; the minimum distance W2 between two adjacent second trenches T2 in the terminal region b around the active region a is selected to be 90% of 5 μm, that is, 4.5 μm. That is, W1>W2.

In one or more embodiments, referring to FIG. 1, in the first plane, the second trench T2 includes a plurality of trench segments 4. In each second trench T2, the trench segments 4 a are arranged one by one in a direction surrounding the active region a and are connected end to end to form a discontinuous ring.

In one or more embodiments, referring to FIG. 1, in the first plane, in each second trench T2, two adjacent trench segments 4a are equally spaced at the third interval W3, the length of the trench segment 4a in the first plane is less than or equal to five times the second interval W2, and the length of the trench segment 4a is greater than or equal to the third interval W3.

In one or more embodiments, referring to FIG. 1, in the first plane, viewed along any direction orthogonal to the first direction, the gaps between the trench segments 4a in any two adjacent second trenches T2 are mutually staggered.

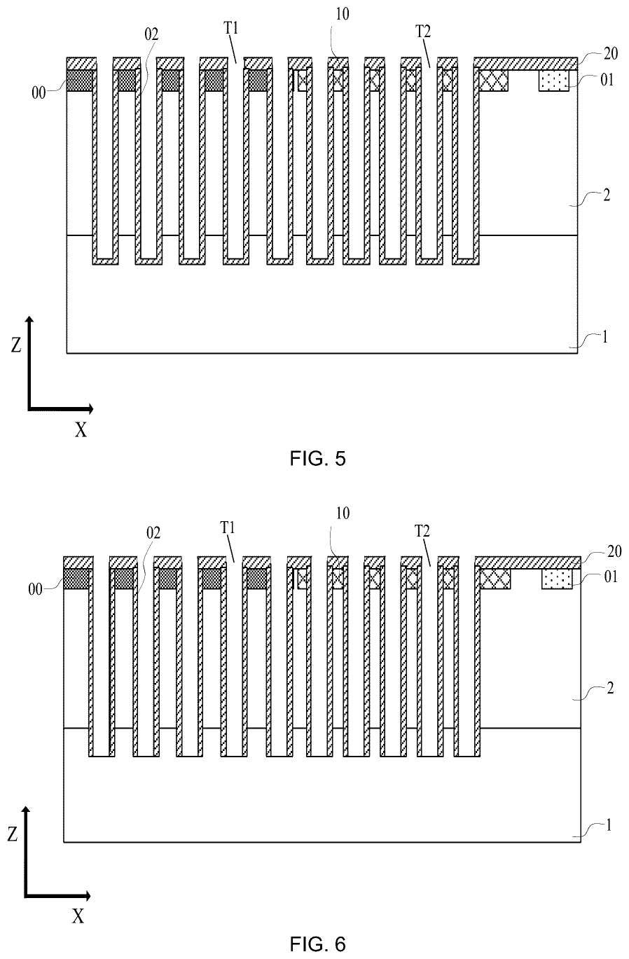

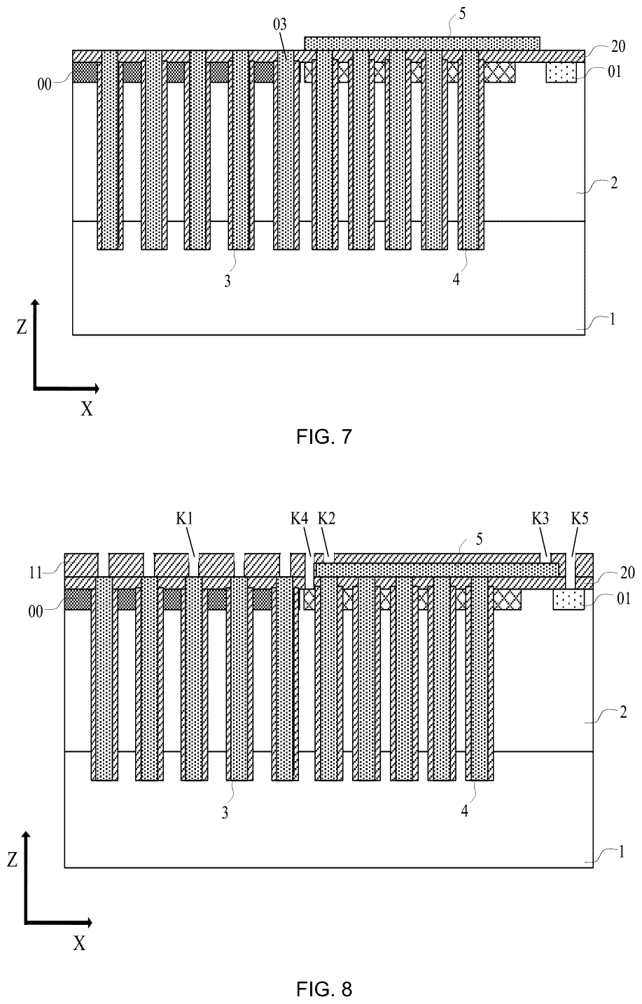

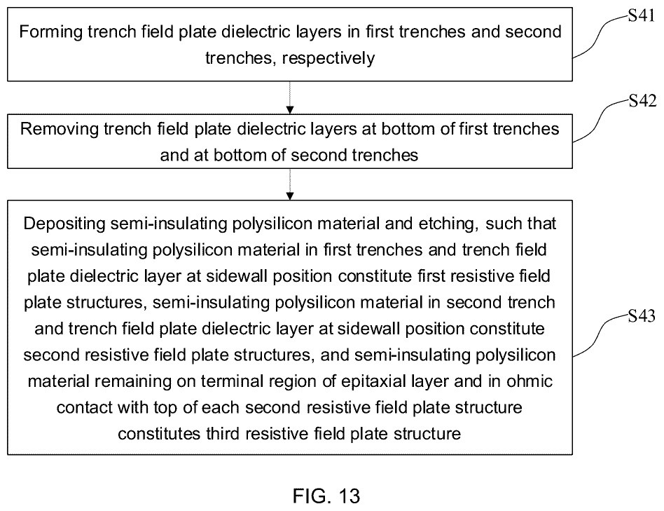

In one or more embodiments, as shown in FIGS. 5 to 7, and FIG. 13, S4 of forming a first resistive field plate structure 3 in the first trench T1, forming a second resistive field plate structure 4 in the second trench T2, and forming a third resistive field plate structure 5 on the terminal region b of the epitaxial layer 2 includes: S41) as shown in FIG. 5, forming a trench field plate dielectric layer 02 in the first trench T1 and the second trench T2, respectively; S42) as shown in FIG. 6, removing the trench field plate dielectric layer 02 at the bottom of the first trench T1 and the bottom of the second trench T2; and S43) as shown in FIG. 7, depositing a semi-insulating polysilicon material 03 and performing etching, such that the semi-insulating polysilicon material 03 in the first trench T1 and the trench field plate dielectric layer 02 at the sidewall position constitute a first resistive field plate structure 3, the semi-insulating polysilicon material 03 in the second trench T2 and the trench field plate dielectric layer 02 at the sidewall position constitute a second resistive field plate structure 4, and the semi-insulating polysilicon material 03 remaining on the terminal region b of the epitaxial layer 2 and in ohmic contact with the top of each second resistive field plate structure 4 constitutes a third resistive field plate structure 5.

In one or more embodiments, as shown in FIG. 5, in S41, a general thermal oxidation process is used to oxidize the bottom and sidewalls of the first trench T1 and the second trench T2 to obtain a trench field plate dielectric layer 02. For example, wet oxidation at 950° C. is performed for 90 min to obtain a trench field plate dielectric layer 02 with a thickness of about 200 nm±10 nm.

In one or more embodiments, as shown in FIG. 6, in S42, the trench field plate dielectric layer 02 at the bottom of the first trench T1 and the second trench T2 is removed by anisotropic dry etching, but the trench field plate dielectric layer 02 at the sidewalls of the first trench T1 and the second trench T2 is retained.

In one or more embodiments, as shown in FIG. 7, in S43, the first trench T1 and the second trench T2 are filled with a semi-insulating polysilicon material 03, such as by using a low-pressure chemical vapor deposition process, with a deposition thickness of 1.2 μm±0.1 μm; the semi-insulating polysilicon material 03 is selectively etched to retain the semi-insulating polysilicon material 03 in the first trench T1 and the second trench T2 to form a first resistive field plate structure 3 and a second resistive field plate structure 4, and a photolithography plate is used to retain the surface semi-insulating polysilicon material 03 between the second electrode 7 and the third electrode 8 in the terminal region b without being reversely etched to form a third resistive field plate structure 5.

In one or more embodiments, as shown in FIG. 7, the third resistive field plate structure 5 is horizontally laterally arranged on the surface of the terminal region b of the epitaxial layer 2, and the third resistive field plate structure 5 is in ohmic contact with the top of each second resistive field plate structure 4.

It should be noted that the third resistive field plate structure 5 may be a composite structure of a resistive field plate and a metal field plate, which includes both a resistive field plate and a metal field plate. If both a metal field plate and a resistive field plate exist, the metal field plate is located below the resistive field plate and is closer to the surface of the epitaxial layer 2. Please refer to the conventional technique for more details, which will not be repeated here.

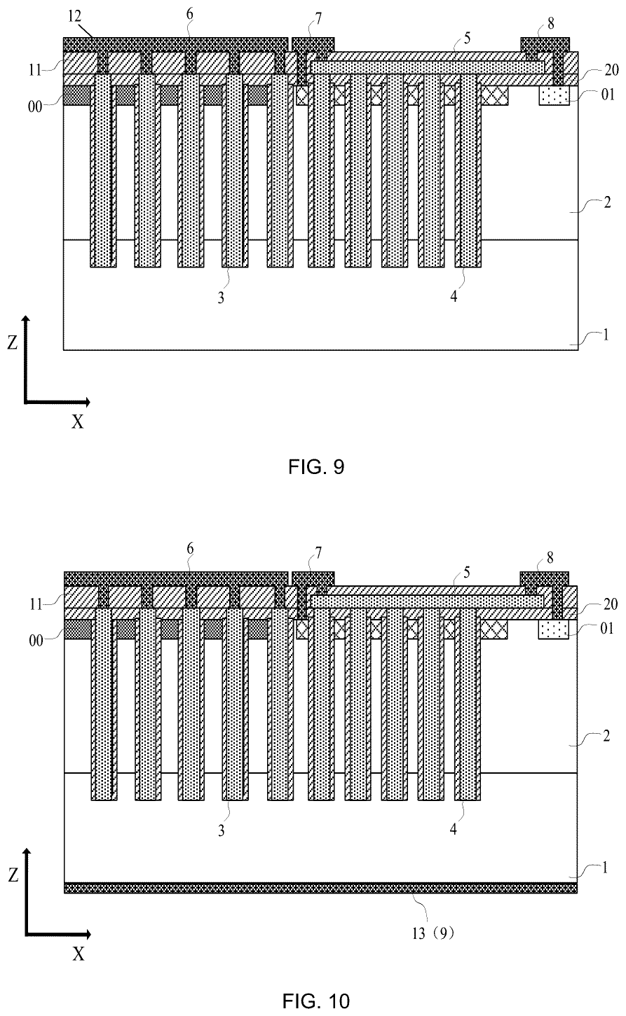

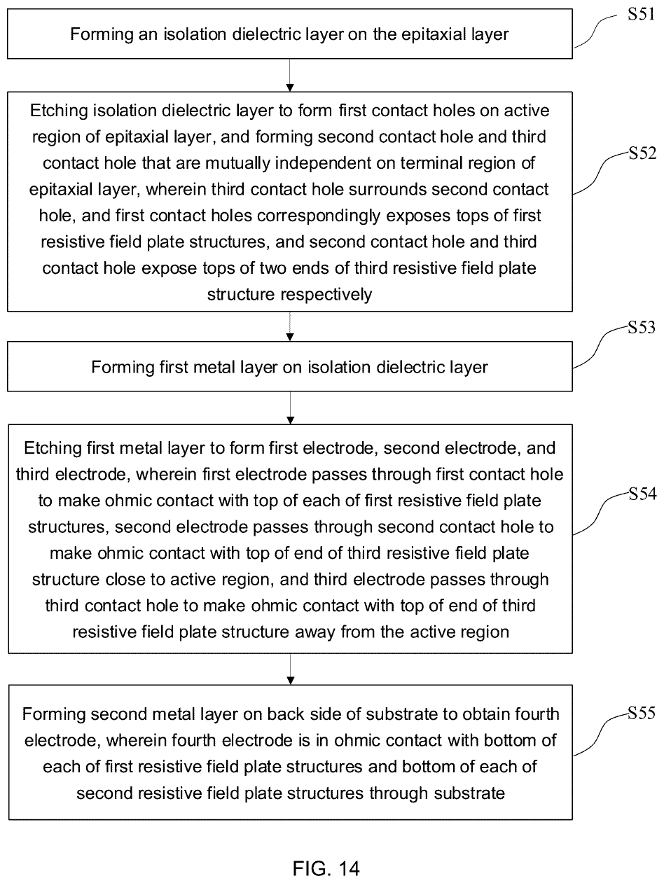

In one or more embodiments, as shown in FIGS. 8 to 10, and FIG. 14, the S5 of forming a first electrode 6, a second electrode 7, and a third electrode 8 that are mutually independent on the epitaxial layer 2 and forming a fourth electrode 9 on the back side of the substrate 1 includes: S51) as shown in FIG. 8, forming an isolation dielectric layer 11 on the epitaxial layer 2; S52) as shown in FIG. 8, etching the isolation dielectric layer 11, forming a plurality of first contact holes K1 on the active region a of the epitaxial layer 2, forming a second contact hole K2 and a third contact hole K3 which are mutually independent on the terminal region b of the epitaxial layer 2, wherein the third contact hole K3 surrounds the second contact hole K2, the plurality of first contact holes K1 correspondingly expose tops of the plurality of first resistive field plate structures 3, and the second contact holes K2 and the third contact holes K3 expose tops of the third resistive field plate structure 5, respectively; S53) as shown in FIG. 9, forming a first metal layer 12 on the isolation dielectric layer 11; S54) as shown in FIG. 9, etching the first metal layer 12 to form the first electrode 6, the second electrode 7, and the third electrode 8, wherein the first electrode 6 passes through the first contact hole K1 to make ohmic contact with the top of each first resistive field plate structure 3, the second electrode 7 passes through the second contact hole K2 to make ohmic contact with the top of the third resistive field plate structure 5 at an end close to the active region a, and the third electrode 8 passes through the third contact hole K3 to make ohmic contact with the top of the third resistive field plate structure 5 at an end away from the active region a; and S55) as shown in FIG. 10, a second metal layer 13 is formed on the back side of the substrate 1 to obtain a fourth electrode 9, wherein the fourth electrode 9 is in ohmic contact with the bottom of each first resistive field plate structure 3 and the bottom of each second resistive field plate structure 4 through the substrate 1.

In one or more embodiments, as shown in FIG. 8, in S52, the isolation dielectric layer 11 and the top dielectric layer 20 in some areas are etched to form a plurality of first contact holes K1 on the active region a of the epitaxial layer 2, and a second contact holes K2 and a third contact holes K3 that are mutually independent on the terminal region b of the epitaxial layer 2. The third contact hole K3 surrounds the second contact hole K2, the plurality of first contact holes K1 correspondingly expose tops of the plurality of first resistive field plate structures 3, and the second contact holes K2 and the third contact holes K3 expose tops of the third resistive field plate structure 5, respectively. In addition, a fourth contact hole K4 exposing the PN junction terminal voltage-withstanding area 10 and a fifth contact hole K5 exposing the equipotential ring 01 are formed on the terminal region b of the epitaxial layer 2.

Each of the first contact holes K1 extends along the second direction in the first plane, and the first contact holes K1 are arranged at intervals along the third direction in the first plane.

In one or more embodiments, as shown in FIG. 9, in S54, the first metal layer 12 is etched to form a first electrode 6, a second electrode 7, and a third electrode 8. The first electrode 6 passes through the first contact hole K1 to make ohmic contact with the top of each first resistive field plate structure 3, the second electrode 7 passes through the second contact hole K2 to make ohmic contact with the top of the third resistive field plate structure 5 at an end close to the active region a, the second electrode 7 also passes through the fourth contact hole K4 to make ohmic contact with the PN junction terminal voltage-withstanding region 10, the third electrode 8 passes through the third contact hole K3 to make ohmic contact with the top of the third resistive field plate structure 5 at an end away from the active region a, and the third electrode 8 also passes through the fifth contact hole K5 to make ohmic contact with the equipotential ring 01.

In one or more embodiments, as shown in FIG. 10, in S55, the back side of the substrate 1 is first thinned, and then a second metal layer 13 is formed on the back side of the substrate 1 to obtain a fourth electrode 9. The fourth electrode 9 is in ohmic contact with the bottom of each first resistive field plate structure 3 and the bottom of each second resistive field plate structure 4 through the substrate 1.

Finally, a high-voltage power semiconductor device as shown in FIG. 10 or FIG. 1 is obtained. In the high-voltage power semiconductor device of the present application, a plurality of second resistive field plate structures 4 are arranged in the terminal region b of the epitaxial layer 2, passing through the epitaxial layer 2 along the first direction and extending into the substrate, and the second resistive field plate structure 4 are arranged concentrically and in a broken way (discontinuously) around the active region a in the first plane, and the second resistive field plate structures 4 and the third resistive field plate structure 5 thereon form a rr-type combined resistive field plate structure. When voltage is applied, the tightly coupled second resistive field plate structures 4 form a uniform three-dimensional electric field distribution that is open and divergent in all directions, thereby optimizing the guiding and binding effect of the terminal region on the charges in the space depletion region in the active region. As a result, the voltage-withstanding performance of the entire power semiconductor device is improved. In addition, the three-dimensional electric field formed has gaps, which may appropriately disperse the space charge, so as not to make the power line too concentrated, and improve the structural stability of the terminal region and the entire high-voltage power semiconductor device. The second resistive field plate structure 4 and the third resistive field plate structure 5 in the terminal region b and the first resistive field plate structure 3 in the active region a are all second-generation super-junction technology based on internal resistive field plates, so that the processes of the active region a and the terminal region b are compatible, the manufacturing cost is low, and the process difficulty is low. In terms of process, a modern 2.5-dimensional three-dimensional processing technology based on deep-trench etching is adopted, which is conducive to the miniaturization design and high-density design of the structure, and is more suitable for the development direction of modern integrated semiconductor devices beyond Moore's law. In one or more embodiments of the present application, the technical solution of the present application is used to make a high-voltage diode structure, and a breakdown voltage of 500V is achieved by using 3.6 Ω·cm N-type drift region material and 27 μm deep-trench internal resistive field plate structure.

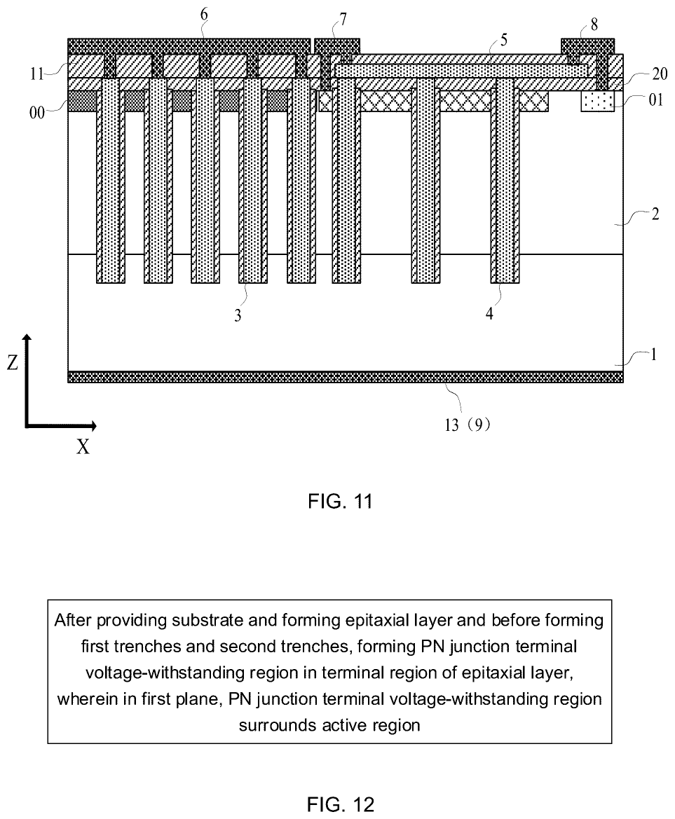

FIG. 10 shows a structural cross-sectional view of the high-voltage power semiconductor device along the section line AA′ in FIG. 1, which displays all the second resistive field plate structures 4 across the terminal region b. However, since the gaps between the trench segments 4a in any two adjacent second trenches T2 are mutually staggered when viewed from any orthogonal direction along the first direction (such as the section line AA′, the section line BB′ or the section line CC′ in FIG. 1), the structural cross-sectional view of the high-voltage power semiconductor device along the section line BB′ in FIG. 1, as shown in FIG. 11, only shows part of the second resistive field plate structure 4 across in the terminal region b.

It should be noted that the above steps are only one of the multiple orders for realizing the technical solution of deep-trench type internal resistive field plate high-voltage power semiconductor device. Other orders that can also realize similar structures and their own functions are also feasible. For example, similar structures and effects can be obtained by only exchanging the steps S3-S4 for forming the first resistive field plate structure 3, the second resistive field plate structure 4, and the third resistive field plate structure 5 with the step S2 and keeping the other steps basically unchanged. Not only that, the specific parameters and sequences of the process can also be as many as countless specific implementation sequences and their combinations to obtain almost the same structure and function, which will not be listed here one by one. In addition, the steps of the above embodiments omit the well-known and obvious simple processes and conditions such as general cleaning in the industry, which are well-known to the general technicians in this field and will not be described in detail here.

The power semiconductor device and the method for manufacturing the same according to the present application may have the following beneficial effects.

1) In the terminal region of the epitaxial layer, a plurality of second resistive field plate structures is arranged along the first direction through the epitaxial layer and extending into the substrate, and the second resistive field plate structures are arranged concentrically and discontinuously around the active region in the first plane. When voltage is applied, those tightly coupled second resistive field plate structures form a uniform three-dimensional electric field distribution that is open and divergent in all directions, thereby optimizing the guiding and binding effect of the terminal region on the charges in the space depletion region in the active region, and improving the voltage-withstanding performance of the entire power semiconductor device. In addition, the three-dimensional electric field formed has gaps, which may appropriately disperse the space charges, so as not to make the power lines too concentrated, thereby improving the structural stability of the terminal region and the entire high-voltage power semiconductor device.

2) The second resistive field plate structures in the terminal region and the first resistive field plate structures in the active region are both second-generation super-junction technology based on the internal resistive field plate, which makes the process of the active region and the terminal region compatible, with low manufacturing cost and low process difficulty.

3) The modern 2.5-dimensional processing technology based on deep trench etching is adopted, which is conducive to the miniaturization and high-density design of the structure, and is more in line with the development direction of modern integrated semiconductor devices beyond Moore's Law.

The three-dimensional electric field formed has gaps, which may appropriately keep the continuity of the electric lines and prevent the electric field from being overly concentrated, thereby improving the structural stability of the terminal region and the entire high-voltage power semiconductor device.

The above embodiments are merely illustrative of the principles and effects of the present application, and are not intended to limit the present application. Anyone familiar with the art may modify or alter the above embodiments without departing from the spirit and scope of the present application. Therefore, all equivalent modifications or alterations made by a person of ordinary skill in the art without departing from the spirit and technical concept disclosed by the present application shall still be covered by the claims of the present application.

What is claimed is:

1. A high-voltage power semiconductor device, comprising:
a substrate comprising a front side and a back side arranged opposite to each other;
an epitaxial layer arranged on the front side of the substrate, wherein the epitaxial layer comprises an active region and a terminal region arranged adjacently to each other in a first plane, and the terminal region surrounds the active region;
a cell functional unit arranged in the active region;
a plurality of first resistive field plate structures arranged in the active region of the epitaxial layer and extending through the epitaxial layer along a first direction into the substrate, wherein the plurality of first resistive field plate structures extends in the first plane along a second direction;
a plurality of second resistive field plate structures arranged in the terminal region of the epitaxial layer and extending through the epitaxial layer along the first direction into the substrate, wherein the plurality of second resistive field plate structures is concentrically arranged in the first plane, and the plurality of the second resistive field plate structures discontinuously surrounds the active region in the first plane;
a third resistive field plate structure arranged on the terminal region of the epitaxial layer and making ohmic contact with a top of each of the plurality of the second resistive field plate structures;
a first electrode arranged on the active region of the epitaxial layer and making ohmic contact with a top of each of the plurality of the first resistive field plate structures;
a second electrode arranged on the epitaxial layer at a junction of the active region and the terminal region, wherein the second electrode is in ohmic contact with a side of the third resistive field plate structure close to the active region;
a third electrode arranged on a side of the terminal region of the epitaxial layer away from the active region and making ohmic contact with the third resistive field plate structure; and
a fourth electrode arranged on the back side of the substrate and making ohmic contact with a bottom of each of the plurality of the first resistive field plate structures and a bottom of each of the plurality of the second resistive field plate structures through the substrate,
wherein the first plane is parallel to the front side of the substrate, and the first direction is perpendicular to the first plane.

2. The high-voltage power semiconductor device according to claim 1, wherein
in the first plane, the first resistive field plate structures are equally spaced at a first interval along a third direction, and the second resistive field plate structures are equally spaced at a second interval along any direction orthogonal to the first direction,
the second interval is smaller than the first interval, and
the third direction is perpendicular to the second direction.

3. The high-voltage power semiconductor device according to claim 2, wherein
in the first plane, each second resistive field plate structure comprises a plurality of resistive field plate segments, and
in each of the second resistive field plate structures, the plurality of the resistive field plate segments is arranged at intervals around the active region.

4. The high-voltage power semiconductor device according to claim 3, wherein
in the first plane, in each of the second resistive field plate structures, two adjacent resistive field plate segments are equally spaced at a third interval,
a length of the resistive field plate segment is less than or equal to five times the second interval, and
the length of the resistive field plate segment is greater than or equal to the third interval.

5. The high-voltage power semiconductor device according to claim 4, wherein
the high-voltage power semiconductor device comprises a PN junction terminal voltage-withstanding region,
the PN junction terminal voltage-withstanding region is arranged in the terminal region of the epitaxial layer and is located on a top of the epitaxial layer,
in the first plane, the PN junction terminal voltage-withstanding region surrounds the active region,
an inner edge of the PN junction terminal voltage-withstanding region is connected to the second electrode through a metal contact hole,
an outer edge of the PN junction terminal voltage-withstanding region is surrounded by the third electrode, and
each of the second resistive field plate structures passes through the PN junction terminal voltage-withstanding region.

6. The high-voltage power semiconductor device according to claim 5, wherein
the PN junction terminal voltage-withstanding region comprises at least one of a field limiting ring PN junction terminal voltage-withstanding region, a RESURF type PN junction terminal voltage-withstanding region, or a variable doping type PN junction terminal voltage-withstanding region.

7. The high-voltage power semiconductor device according to claim 1, wherein
the cell functional units at least comprise: a diode cell functional unit, a MOSFET cell functional unit, a triode cell functional unit, a JFET cell functional unit, and an IGBT cell functional unit.

8. A method for manufacturing a high-voltage power semiconductor device, comprising:
providing a substrate comprising a front side and a back side arranged opposite to each other, and forming an epitaxial layer on the front side of the substrate, wherein the epitaxial layer comprises an active region and a terminal region arranged adjacent to each other in a first plane, and the terminal region surrounds the active region;
forming a cell functional unit in the active region of the epitaxial layer;
forming first trenches in the active region of the epitaxial layer, and forming second trenches in the terminal region of the epitaxial layer, wherein the first trenches pass through the cell functional unit and the epitaxial layer along a first direction and enter the substrate, and the second trenches pass through the epitaxial layer along the first direction and enter the substrate;
forming first resistive field plate structures in the first trenches, forming second resistive field plate structures in the second trenches, and forming a third resistive field plate structure on a surface of the terminal region of the epitaxial layer, wherein the third resistive field plate structure is in ohmic contact with a top of each of the second resistive field plate structures; and
forming a first electrode, a second electrode, and a third electrode that are mutually independent on the epitaxial layer, and forming a fourth electrode on the back side of the substrate, wherein the first electrode is in ohmic contact with a top of each of the first resistive field plate structures, the second electrode is in ohmic contact with a side of the third resistive field plate structure close to the active region, the third electrode is in ohmic contact with a side of the third resistive field plate structure away from the active region, and the fourth electrode is in ohmic contact with a bottom of each of the first resistive field plate structures and a bottom of each of the second resistive field plate structures through the substrate,
wherein the first plane is parallel to the front side of the substrate, the first direction is perpendicular to the first plane, and the first trench and the second trench are formed in a same process.

9. The method for manufacturing a high-voltage power semiconductor device according to claim 8, further comprising:
after providing the substrate and forming the epitaxial layer and before forming the first trenches and the second trenches, forming a PN junction terminal voltage-withstanding region in the terminal region of the epitaxial layer, wherein in the first plane, the PN junction terminal voltage-withstanding region surrounds the active region.

10. The method for manufacturing a high-voltage power semiconductor device according to claim 9, wherein
in the first plane, each of the first trenches extends in the first plane along a second direction, and each of the first trenches is equally spaced at a first interval along a third direction, the second trenches are arranged concentrically and discontinuously around the active region in the first plane, and the second trenches are equally spaced at a second interval in any direction orthogonal to the first direction, and
the second interval is smaller than the first interval, and the third direction is perpendicular to the second direction.

11. The method for manufacturing a high-voltage power semiconductor device according to claim 10, wherein
in the first plane, each second trench comprises trench segments, and
in each of the second trenches, the trench segments are arranged at intervals around the active region.

12. The method for manufacturing a high-voltage power semiconductor device according to claim 10, wherein
in the first plane, in each of the second trenches, two adjacent trench segments are equally spaced at a third interval, a length of the trench segment is less than or equal to five times the second interval, and the length of the trench segment is greater than or equal to the third interval.

13. The method for manufacturing a high-voltage power semiconductor device according to claim 10, wherein forming the first resistive field plate structures in the first trench, forming the second resistive field plate structures in the second trench, and forming the third resistive field plate structure on the surface of the terminal region of the epitaxial layer comprise:
forming trench field plate dielectric layers in the first trenches and the second trenches, respectively;
removing the trench field plate dielectric layers at a bottom of the first trenches and at a bottom of the second trenches; and
depositing semi-insulating polysilicon material and etching, such that the semi-insulating polysilicon material in the first trenches and the trench field plate dielectric layers at sidewall positions constitute the first resistive field plate structures, the semi-insulating polysilicon material in the second trenches and the trench field plate dielectric layers at the sidewall positions constitute the second resistive field plate structures, and the semi-insulating polysilicon material remaining on the terminal region of the epitaxial layer and in ohmic contact with the top of each second resistive field plate structure constitutes the third resistive field plate structure.

14. The method for manufacturing a high-voltage power semiconductor device according to claim 13, wherein forming the first electrode, the second electrode, and the third electrode that are mutually independent on the epitaxial layer and forming the fourth electrode on the back side of the substrate comprise:
forming an isolation dielectric layer on the epitaxial layer;
etching the isolation dielectric layer to form a plurality of first contact holes on the active region of the epitaxial layer, and forming a second contact hole and a third contact hole that are mutually independent on the terminal region of the epitaxial layer, wherein the third contact hole surrounds the second contact hole, and the plurality of first contact holes correspondingly exposes tops of the first resistive field plate structures, and the second contact hole and the third contact hole expose tops of two ends of the third resistive field plate structure respectively;
forming a first metal layer on the isolation dielectric layer;
etching the first metal layer to form the first electrode, the second electrode, and the third electrode, wherein the first electrode passes through the first contact hole to make ohmic contact with the top of each of the first resistive field plate structures, the second electrode passes through the second contact hole to make ohmic contact with a top of an end of the third resistive field plate structure close to the active region, and the third electrode passes through the third contact hole to make ohmic contact with a top of an end of the third resistive field plate structure away from the active region; and
forming a second metal layer on the back side of the substrate to obtain the fourth electrode, wherein the fourth electrode is in ohmic contact with the bottom of each of the first resistive field plate structures and the bottom of each of the second resistive field plate structures through the substrate.
